(19) United States
(12) Patent Application Publication
(10) Pub. No.: US 2025/0125320 A1
(43) Pub. Date: Apr. 17, 2025

(54) OPTICAL MODULE USING OPTICAL SYSTEM-IN-PACKAGE, AND OPTICAL TRANSCEIVER

(71) Applicant: LIPAC CO., LTD., Seoul (KR)

(72) Inventor: Seong Wook CHOI, Seoul (KR)

(21) Appl. No.: 18/729,280

(22) PCT Filed: Feb. 14, 2023
(86) PCT No.: PCT/KR2023/002119

§ 371 Date: Jul. 16, 2024

(30) Foreign Application Priority Data
Feb. 14, 2022 (KR) 10-2022-0018846

(51) Int. Cl. H01L 25/16; G02B 6/42; H01L 23/00; H01L 23/31

(52) U.S. Cl. CPC H01L 25/167; G02B 6/4243; G02B 6/4271; G02B 6/428; H01L 23/3128; H01L 24/20; H01L 24/73; G02B 6/4278; H01L 24/13; H01L 2224/13021; H01L 2224/214; H01L 2224/73101; H01L 2924/12043

(57) ABSTRACT

Provided are an optical module and an optical transceiver using an optical system-in-package (O-SIP) including a photonic integrated circuit (IC), an electronic IC, and the like, in a package. The optical module includes: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat, on a lower portion and an upper portion of the mold body, respectively; and a vertical coupler mounted on an upper portion of the O-SIP and having a through hole corresponding to a light entrance/exit part of the photonic IC inside the mold body, wherein an optical fiber is coupled to the through hole.

### TECHNICAL FIELD

The present invention relates to an optical module using an optical system-in-package (O-SIP), and more specifically, to an optical module and an optical transceiver using an optical system-in-package (O-SIP) including photonic integrated circuits (ICs) and electronic ICs in the package.

### BACKGROUND ART

Semiconductor chips may be used to manufacture light receiving devices capable of reacting to light or light emitting devices emitting light, as well as serving as a logic or driving IC. These optical devices are used in various fields, such as optical transceivers in charge of optical connections between servers, or modules that transmit image data between TVs and set-top boxes, or between virtual reality (VR) glasses and graphics processing units (GPUs).

Further, other applications of the optical devices may be used in a proximity sensor, a time of flight (ToF) sensor, a light detection and ranging (LIDAR) device, and the like, which include a light emitting device.

Optical devices should be used together with electronic devices that drive or interface the optical devices, thereby converting optical signals into electronic signals. For example, in the field of transmitting optical data, an optical device and an electronic device may be used together for a module for converting an optical signal into a digital signal. As another example, in the optical sensor field, a device for converting characteristics of received light into image data or depth data may be used together with an optical device.

In all of the above conventional applications, a plurality of chips are mounted using a printed circuit board (PCB) in which a wiring pattern is mostly manufactured and connected by wire-bonding. This is a chip-on-board (CoB) type package.

In addition, instead of a package using a PCB, an optical/electric device may be packaged at a wafer level using a semiconductor package method based on a fan-out wafer level package (FOWLP) process, which is a technology that may increase performance by using a high-precision redistribution layer (RDL) while producing an ultra-thin package.

When the optical/electric package is performed using the semiconductor package, most of optical paths may be perpendicular to light emitting device chips, so that the optical paths may be arranged on one surface of the package, and a terminal pad for electrical connection with the outside may be formed on the opposite surface of the package. In addition, the redistribution layer for connecting between chips molded therein is arranged on one surface of the optical/electric package having the optical path.

### DISCLOSURE

### Technical Problem

A task of the present invention is to solve a problem of having to form a conductive via through a package for connection with a fan-out terminal pad arranged on a second surface opposite to a first surface of the package because the fan-out terminal pad is arranged on the opposite surface of the package when performing an optical/electric package by using a semiconductor package.

In order to include a conductive via in a package, an additional process or a method of packaging a PCB on which the conductive via is formed or a conductive via structure together, is used in a semiconductor packaging operation. The generation of the conductive via has a disadvantage in that a material cost or a process cost increases.

Furthermore, because the RDL and the terminal pad that interconnect molded chips inside the package are located opposite to each other in a package using the conductive via, the terminal pad may only be arranged in the form of a fan-out and may not be arranged in the form of a fan-in unless wiring layers inside the package are manufactured on both sides of the terminal pad. When terminal pads are arranged only in the form of a fan-out, while excluding the arrangement of terminal pads in the form of a Fan-In including an area where a chip is located, the advantage of integration is lost due to an increase in an area of the package.

Therefore, in order to solve the problem of not being able to arrange the terminal pads in the Fan-In form, RDLs may be formed on both sides of the package to produce Fan-In and Fan-Out type pads, but this causes an increase in a process cost. In particular, since efforts should be made to precisely align the RDL patterns placed on both sides of the package, this increases the cost rather than simply increasing the RDL placed on one side. In addition, when the RDLs are formed on both sides of the package, a heat transfer path may be hindered when a molded chip is radiated through a lower part of the package due to the addition of the RDL at the lower part of the package.

In addition, it is very important to design a heat dissipation structure when using an optical chip. This is because a lot of heat is not only generated in the optical chip, but the light emitting conditions or light receiving conditions of the optical chip are also often temperature-sensitive. Thus, heat dissipation design is a very important part. In all of the existing package methods of using CoB or semiconductor packaging, if a heat dissipation structure (a structure connected to a heat sink or metal housing) is placed on a light emitting surface of the package, the optical path is hidden by the heat dissipation structure and thus, the heat dissipation structure is generally placed on the other side of the light emitting surface of the package.

Therefore, most of the heat dissipation path consists of a surface where the terminal pad of the package is located, and in this case, since the surface where the terminal pad of the package is formed is connected to a main PCB of an optical transceiver, most of the heat dissipation of the package occurs through a thermal via of the main PCB. Therefore, the conventional method has a problem in that the heat dissipation path between the heat dissipation structure and the chip is interrupted by the PCB.

In the present invention, in order to solve the above-described problems, an optical module and an optical transceiver using an optical system-in-package (O-SIP) including a photonic IC and an electronic IC in the package, may be provided.

### Technical Solution

According to an aspect of an embodiment of the present invention, there is provided an optical module including: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat, on a lower portion and an upper portion of the mold body, respectively; and a vertical coupler mounted on an upper portion of the O-SIP and having a through hole corresponding to a light entrance/exit part of the photonic IC inside the mold body, wherein an optical fiber is coupled to the through hole.

The O-SIP may include an transmitter optical sub-assembly (TOSA) to which a light emitting device is applied as the photonic IC and an receiver optical sub-assembly (ROSA) to which a light receiving device is applied as the photonic IC.

In addition, the photonic IC may include a light emitting device and a light receiving device.

According to another embodiment of the present invention, the optical module may further include: first and second metal structures for heat dissipation having respective upper surfaces bonded to lower portions of the photonic IC and the electronic IC and respective lower surfaces exposed; a third metal structure for a via that is inserted through the mold body between the photonic IC and the electronic IC, and has an upper end connected to a redistribution layer (RDL) and a lower end exposed; and a metal connection layer that connects the RDL to the lower portions of the photonic IC and the electronic IC and has a lower surface of the metal connection layer exposed by interconnecting the lower surfaces of the first to third metal structures.

The O-SIP may include the mold body having a first surface and a second surface, which are flat on a lower portion and an upper portion of the mold body, respectively; the photonic integrated circuit (IC) molded inside the mold body to expose a bonding pad on the first surface; the electronic IC molded to be spaced apart from the photonic IC inside the mold body to expose a bonding pad on the first surface; and an redistribution layer (RDL) formed on the second surface of the mold body and having a plurality of fan-out terminal pads electrically connected to the outside while interconnecting the photonic IC and the electronic IC.

In this case, the RDL arranged on an upper portion of the light entrance/exit part of the photonic IC may have an opening.

According to another aspect of an embodiment of the present invention, there is provided an optical module including: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body, respectively; an optical fiber holder coupled to a rear end portion of an optical fiber to support at least one optical fiber therein and having a pair of coupling recesses; and a vertical coupler having a lower surface mounted on an upper portion of the O-SIP, having an accommodation space for accommodating the optical fiber holder at an upper end thereof, and having a pair of coupling protrusions protruding from both sides thereof to be coupled to the pair of coupling recesses.

In this case, when the optical fiber holder is coupled to the accommodation space of the vertical coupler, a plurality of optical fibers may be optically aligned with light entrance/exit part of a light emitting device or a light receiving device of the O-SIP.

According to another aspect of an embodiment of the present invention, there is provided an optical module including: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body, respectively; a first printed circuit board (PCB) having the O-SIP mounted on the lower surface thereof, and a through hole forming an optical path when an optical signal is generated in a vertical direction or an optical signal is received from the photonic IC at a portion corresponding to a light entrance/exit part of the photonic IC; and an optical fiber holder coupled to rear end portions of a plurality of optical fibers so as to support the plurality of optical fibers therein, and having a front end portion on which the O-SIP is mounted through the through hole.

In this case, the first PCB may be a flexible PCB, and the optical module may further include a second PCB on which a plurality of electronic components for performing a transmission and reception control for the O-SIP are mounted wherein one end of the PCB is connected to the second PCB.

According to another aspect of an embodiment of the present invention, there is provided an optical transceiver including: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body, respectively; a printed circuit board (PCB) having the O-SIP mounted on the lower surface thereof, and a through hole forming an optical path when an optical signal is generated in a vertical direction or an optical signal is received from the photonic IC at a portion corresponding to a light entrance/exit part of the photonic IC; and a Lucent connector (LC) receptacle having a rear end portion coupled to the PCB and a front end portion coupled to an optical fiber.

In this case, the optical module according to an embodiment of the present disclosure may further include a thermo electric cooler (TEC) mounted on a rear surface of the O-SIP to cool the O-SIP.

According to another aspect of an embodiment of the present invention, there is provided an optical transceiver including: an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body, respectively; a printed circuit board (PCB) having the O-SIP mounted on the lower surface thereof, and a through hole forming an optical path when an optical signal is generated in a vertical direction or an optical signal is received from the photonic IC at a portion corresponding to a light entrance/exit part of the photonic IC; and a Lucent connector (LC) receptacle having a rear end accommodation space accommodating a printed circuit board (PCB) on which the O-SIP is mounted and a front end portion coupled to an optical fiber.

In this case, a sealing agent for sealing the PCB on which the O-SIP is mounted may be filled in a rear surface of the rear end accommodation space of the LC receptacle.

According to another aspect of an embodiment of the present invention, there is provided an optical transceiver including an optical module and a housing accommodating the optical module therein.

In order to solve the problems existing in an optical package manufactured using a conductive via in a fan-out wafer level package (FOWLP), the present invention provides an optical system-in-package (O-SIP), and an optical module and an optical transceiver using the O-SIP in which a photonic integrated circuit (IC) and an electronic IC are included in a package by using an optical FOWLP that does not use a conductive via. The O-SIP may include an optical engine module.

The photonic IC and the electronic IC may be molded in a package, and an exposed surface of an IC having a terminal pad and a light output/input part may be molded to face a redistribution layer (RDL). The RDL may be arranged on the mold, and an external connection terminal pad may be arranged on the RDL. A microlens, an optical system, a metasurface, or a layer having various patterns may be manufactured at a wafer level through an additional micro electro mechanical system (MEMS) or imprint process on the RDL.

In the related art, glass is used as a lens to refract light to sharpen an image or to amplify the image. However, a meta-surface serving as a metalens may have a structure such as a nano-sized column or pin, thereby concentrating light without image distortion.

When packaging is performed in the above-described FOWLP form, for example, when a surface mount technology (SMT) is applied to a main PCB in which an optical transceiver is embedded, the light output/input part may be blocked due to the main PCB. To solve this problem, according to the present invention, it is possible to solve the problem by manufacturing a light entrance/exit part by making a through hole or using a transparent material in the main PCB. Thereafter, optical components such as necessary lenses and optical fibers may be assembled on the main PCB.

Furthermore, in the present invention, metal structures which are molded for the heat dissipation of the photonic IC and the electronic IC, may be arranged below the photonic IC and the electronic IC. The surfaces of the metal structures are opened to expose the metal structures on the opposite surface of the package facing the RDL of the FOWLP, and the exposed metal structures are connected to heat dissipation structures such as a heat sink or a thermal interface material (TIM) to form a heat dissipation path.

In addition, in order to electrically connect the photonic IC and the lower portion of the electronic IC, the metal structures may be connected to the RDL located on the upper surface of the FOWLP. In this case, a metal may be deposited on the entire lower surface of the FOWLP at a wafer level to form a metal connection layer, and then the metal structure and the RDL of the FOWLP may be connected to the conductive via or the metal structures may be electrically connected therebetween by the metal connection layer.

Furthermore, in the O-SIP of the present invention, the photonic IC is an integrated circuit that performs optical processing, and converts an optical signal into an electrical signal or converts an electrical signal into an optical signal. For example, the photonic IC 130 may be a chip, which includes light emitting devices such as vertical-cavity surface-emitting lasers (VCSEL) and laser diodes (LD), or photodiodes (PD), avalanche photodiodes (APD), a complementary metal oxide semiconductor (CMOS) image sensor (CIS), a charge coupled device (CCD) image sensor, and a time of flight (ToF) sensor, in which a plurality of photodiodes (PD) are arranged in an array, and additionally includes a circuit that provides the CIS, the CCD image sensor, and the ToF sensor with an additional function or is in charge of signal processing.

The APD is a photodiode (PD) having an optical current amplification mechanism therein, and may be widely used as an optical detector in transmitter optical.

In addition, the electronic IC is used to operate according to the photonic IC. For example, when the photonic IC is a photodiode, the electronic IC may operate together with a transimpedance amplifier for amplifying an electrical signal due to a collision of photons on the photodiode. When the photonic IC is a light emitting device, the electronic IC may use a driving circuit for driving the light emitting device.

Furthermore, the O-SIP of the present invention may use a chip that includes a PD, an APD, a CIS, a CCD image sensor, and a ToF sensor, and additionally includes a signal processing device as a circuit or an IC for providing the PD, APD, CIS, CCD image sensor, and ToF sensor with additional functions or being in charge of processing signals.

In addition, the O-SIP of the present invention may include the photonic IC which includes all of light emitting devices such as vertical-cavity surface-emitting lasers (VCSEL) and laser diodes (LD), or light receiving devices such as photodiodes (PD), avalanche photodiodes (APD), a complementary metal oxide semiconductor (CMOS) image sensor (CIS), a charge coupled device (CCD) image sensor, and a time of flight (ToF) sensor, in which a plurality of photodiodes (PD) are arranged in an array, and an electronic IC for driving the photonic IC.

The present invention provides an O-SIP in which a plurality of photonic ICs and electronic ICs are located inside a package formed in an SIP form without using a separate substrate, and an optical path between the photonic IC and the outside of the SIP is formed. The O-SIP of the present invention enables smaller and inexpensive optical transceivers as the substrate usage is excluded.

In the present invention, a slim O-SIP may be implemented by packaging the photonic IC and the electronic IC by using a fan-out technology of pulling out input/output (I/O) terminals thereby increasing the I/O terminals, that is, a fan-out wafer level package (FOWLP) technology, when the electronic IC (such as a chip) operating according to the photonic IC is integrated, without wire-bonding, by using a flip chip package technology together with the photonic IC, while devices are integrated without using a substrate.

In order to fix a chip (die) without using a substrate such as a PCB, the O-SIP, which is a kind of SIP technology, may miniaturize and slim at a level of 1/16 or so compared to a conventional package by packaging using an encapsulation material such as an epoxy mold compound (EMC) and reduce costs.

The optical module obtained by coupling the O-SIP according to the present invention to the main board (that is, the main PCB) or the module board (that is, the module PCB) may not only form a slim structure but also perform heat dissipation through a heat sink or a main body housing made of a metal through a dissipation metal structure attached to the rear surface of the O-SIP instead of the main board (that is, the main PCB), thereby preventing performance degradation.

### Advantageous Effects

As described above, the present invention may solve the problem of a cost increase, the inefficiency of arrangement of a terminal pad, and the deterioration of the heat dissipation performance, which are due to the use of an existing conductive via pointed to as the disadvantage of the FOWLP using the existing conductive via.

In addition, in this invention, arrangement of the Fan-in and Fan-out terminal pads may be used simultaneously, thereby efficiently arranging terminal pads, and as a result, the package size may be reduced when the terminal pad may be further integrated, thereby achieving miniaturization of products and reduction of a process cost.

Moreover, in this invention, it is possible to manufacture a package that exhibits superior heat dissipation performance than an optical package product through a FOWLP using a conventional CoB method and an existing conductive via.

In addition, in the case of using the O-SIP structure of this invention, an optical module with the minimum thickness may be manufactured for each application as described in the following examples.

The optical module obtained by coupling the O-SIP according to the present invention to the main board (that is, the main PCB) or the module board (that is, the module PCB) may not only form a slim structure but also perform heat dissipation through a heat sink or a main body housing made of a metal through a dissipation metal structure attached to the rear surface of the O-SIP instead of the main board (that is, the main PCB), thereby preventing performance degradation.

### BRIEF DESCRIPTION OF THE DRAWINGS

FIG. 1 is a cross-sectional view illustrating a package in which a photonic integrated circuit (IC) using a light emitting device and an electronic IC are embedded in an optical system-in-package (O-SIP) using semiconductor packaging according to a first embodiment of the present invention.

FIG. 2 is a cross-sectional view of a modified example in which a partial or entire opening is formed in a redistribution layer in an O-SIP using semiconductor packaging according to the first embodiment of the present invention.

FIG. 3 is a cross-sectional view illustrating a package in which a photonic IC using a light emitting device and a plurality of electronic ICs are embedded in an O-SIP using semiconductor packaging according to a second embodiment of the present invention.

FIG. 4 is a cross-sectional view illustrating a package in which a photonic IC using a light emitting device and a light receiving device and an electronic IC are embedded in an O-SIP using semiconductor packaging according to a third embodiment of the present invention.

FIG. 5 is a cross-sectional view illustrating a package in which a transmitter optical sub-assembly (TOSA) and a receiver optical sub-assembly (ROSA) are separately formed and a heat dissipation metal structure is stacked in an O-SIP using semiconductor packaging according to a fourth embodiment of the present invention.

FIG. 6 is a cross-sectional view illustrating an optical module in which an O-SIP according to the first embodiment is mounted in a main PCB according to a fifth embodiment of the present invention.

FIG. 7 is a cross-sectional view illustrating an optical module according to a sixth embodiment of the present invention in which a vertical coupler is coupled to the O-SIP according to the first embodiment.

FIGS. 8A and 8B are cross-sectional views illustrating a process of manufacturing an O-SIP to which a vertical coupler is coupled according to a sixth embodiment of the present invention.

FIG. 9 is a cross-sectional view illustrating an optical module in which an optical fiber is directly coupled to an O-SIP to which a vertical coupler is coupled and obtained according to the sixth embodiment of the present invention.

FIG. 10 is a cross-sectional view illustrating an optical module in which a ribbon-shaped optical fiber holder is coupled to an O-SIP to which a vertical coupler is coupled according to a seventh embodiment of the present invention.

FIG. 11 is a cross-sectional view illustrating an optical module in which an O-SIP according to the first embodiment is mounted on a main PCB using a flexible printed circuit board (FPCB) according to an eighth embodiment of the present invention.

FIG. 12 is a longitudinal cross-sectional view of an optical module according to the eighth embodiment of the present invention.

FIG. 13 is an enlarged cross-sectional view illustrating a structure in which an optical fiber holder is directly coupled to an O-SIP in an optical module according to the eighth embodiment of the present invention.

FIG. 14 is a partial enlarged view of an optical module according to the eighth embodiment of the present invention.

FIG. 15 is a cross-sectional view illustrating an optical transceiver implemented using an optical module according to the eighth embodiment of the present invention.

FIG. 16 is a cross-sectional view illustrating an optical transceiver in which an optical module using an O-SIP according to the first embodiment is connected to an optical fiber using a Lucent connection (LC) receptacle according to a ninth embodiment of the present invention.

FIG. 17 is a cross-sectional view illustrating an optical transceiver in which an optical module using an O-SIP according to the first embodiment is connected to the LC receptacle according to the ninth embodiment of the present invention.

FIG. 18 is a cross-sectional view illustrating an optical transceiver in which an optical module in which an O-SIP according to the first embodiment is mounted on a main PCB according to a tenth embodiment of the present invention is combined with a LC receptacle and then sealed.

### BEST MODE FOR CARRYING OUT THE INVENTION

Hereinafter, embodiments of the present invention will be described in detail with reference to the accompanying drawings.

The sizes and shapes of the components shown in the drawings may be exaggerated for clarity and convenience. In addition, terms defined in consideration of the configuration and operation of the present invention may vary depending on the intention or custom of the user, the operator, and the like. Definitions of these terms should be based on the content of this specification.

In general, semiconductor packages are required to play four major roles: mechanical protection, electrical connection, mechanical connection, and heat dissipation.

Semiconductor packages cover semiconductor chips/devices with package materials such as epoxy mold compound (EMC) to protect the semiconductor chips/devices from external mechanical and chemical impacts.

Each semiconductor package serves to connect a physically/electrically molded chip to a system. Electrically, it is necessary to connect a chip with a system to supply power to the chip, and create a passage through which signals may be input or output so that desired functions may be performed. In addition, the chip should be well connected so as to be well attached to the system while the chip is being used.

At the same time, heat generated in the chip/device should be rapidly dissipated. When a semiconductor product operates, current flows, and when current flows, resistance is inevitably generated and heat is generated accordingly.

A semiconductor package completely surrounds a chip, and if the semiconductor package does not dissipate heat well, the chip may be overheated and the temperature of the device or chip molded inside may rise above an operating temperature, eventually stopping the operation of the device or chip. Therefore, it is essential that semiconductor packages should effectively dissipate heat. As semiconductor products become faster and more functional, the importance of the cooling role of packages is increasing.

A system-in-package (SIP) is configured to have one independent function by stacking or arranging multiple chips in one package. Typically, a SIP includes all parts as a complete system consisting of signal processing devices such as microprocessors and multiple chips containing multiple memories.

The present invention relates to an O-SIP provided on an optical transceiver, etc., which may be mounted on a main PCB to form an optical module, and the optical module may be embedded in the optical transceiver.

The main PCB may include a laser diode driver (LDD) and a clock data recovery (CDR) for a transmitter optical sub-assembly (TOSA), a transimpedance amplifier (TIA)/limiting amplifier (LA) for a receiver optical sub-assembly (ROSA), and a micro controller unit (MCU) for performing overall transmission and reception control of an optical transceiver, which are mounted on the main PCB.

The main PCB may include an analog-to-digital converter (ADC) and a digital-to-analog converter (DAC), to perform signal processing in a digital signal processing method by a microcontroller unit (MCU) and a field programmable gate array (FPGA), and may include a digital signal processor (DSP) and a driver to drive a TOSA and a ROSA. In addition, the main PCB may be configured in various ways.

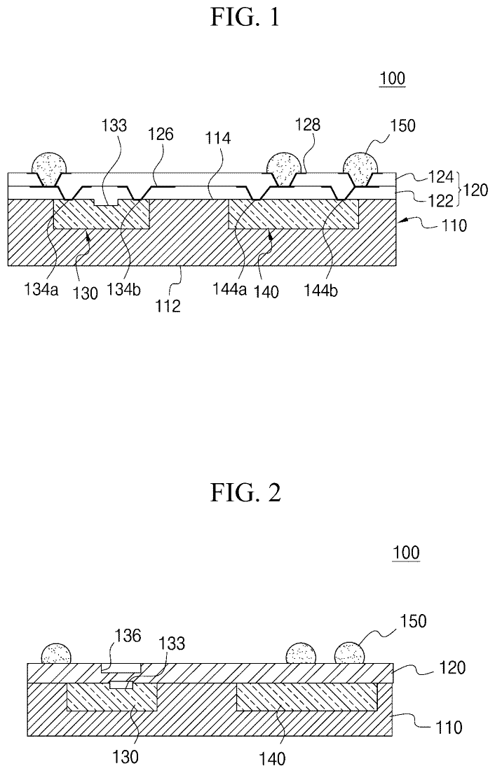

FIG. 1 is a cross-sectional view illustrating a package in which a photonic integrated circuit (IC) and an electronic IC are embedded in an optical system-in-package (O-SIP) using semiconductor packaging according to a first embodiment of the present invention, and FIG. 2 is a cross-sectional view of a modified example in which a partial or entire opening is formed in a redistribution layer in an O-SIP using semiconductor packaging according to the first embodiment of the present invention.

Hereinafter, an O-SIP using a semiconductor packaging according to a first embodiment of the present invention will be described with reference to FIGS. 1 and 2.

The O-SIP 100 according to the first embodiment of the present invention includes a photonic IC 130 and an electronic IC 140 inside a mold body 110, and the mold body 110 has a first surface (or a lower surface) 112 and a second surface (or an upper surface) 114 that face each other and are flat. A redistribution layer (RDL) 120 including a plurality of terminal pads 150 for external connection of the package may be formed on the second surface (or the upper surface) 114 of the mold body 110.

The O-SIP 100 according to the first embodiment of the present invention may be implemented into a slim O-SIP 100 while completely solving a height tolerance due to a wiring between devices by packaging the photonic IC 130 and the electronic IC 140 by using a fan-out technology of pulling out input/output (I/O) terminals thereby increasing the I/O terminals, that is, a fan-out wafer level package (FOWLP) technology, when the photonic IC 130 and the electronic IC 140 are integrated, without wire-bonding, by using a flip chip package technology, while the devices are integrated without using a substrate. The O-SIP 100 may miniaturize and slim at a level of 1/16 or so compared to a package of using a conventional PCB and reduce costs.

In the case of the O-SIP 100, the photonic IC 130 and the electronic IC 140 are integrated in a flip chip form without using a substrate such as a PCB as a kind of system-in-package (SIP) technology, and, for example, the mold body 110 is formed by packaging the photonic IC 130 and the electronic IC 140 by using an encapsulation material such as an epoxy mold compound (EMC) for fixing a chip (die).

As a result, the mold body 110 serves to safely protect, from impact, an optical engine module, which is packaged after being integrated. The O-SIP 100 including the photonic IC 130 and the electronic IC 140 in the mold body 110 may constitute an optical engine module.

In addition, the O-SIP 100 may be obtained as a semiconductor package type, by performing a manufacturing process using a semiconductor process in units of wafers, then integrally forming a redistribution layer 120 including a plurality of terminal pads 150 on the second surface 114 of the package, and performing a dicing process that individually separates the O-SIP 100.

The photonic IC unit 130 and the electronic IC unit 140 are molded in a package, and terminal pads 150 each on which a solder ball for electrical connection is mounted, are arranged above the second surface 114 of the mold body 110, and the light output/input part 133 is arranged on the second surface 114 of the mold body 110. The photonic IC 130 is an integrated circuit (IC) that performs optical processing, and serves to convert an optical signal into an electrical signal or an electrical signal into an optical signal.

For example, the photonic IC 130 may use a chip additionally including a light emitting device such as a VCSEL and a LD, a light receiving device such as a PD, an APD, a CIS, a CCD image sensor, and a ToF sensor, and a signal processing device as a circuit or IC that provides the light emitting device and the light receiving device with additional functionality or is responsible for signal processing.

In addition, the photonic IC 130 may include a planar lightwave circuit (PLC), in which a waveguide may be formed on a flat chip to perform functions such as a beam splitter, a modulator, a wavelength division multiplexing (WDM), and the like.

The electronic IC 140 may include an IC that performs electrical signal processing, a function of receiving an electrical signal from the photonic IC 130 and amplifying/converting the electrical signal, and the like, and may include an individual IC and an integrated IC that serve as a laser diode (LD) driver IC, clock data recovery (CDR), equalizer, transimpedance amplifier (TIA), inter-integrated circuit (I2C) communication, digital signal processing (DSP), and the like.

In addition, the O-SIP 100 according to the first embodiment of this invention may further include devices having various functions such as memory, logic processor, and analog driver.

In this case, various materials including a semiconductor material such as GaAs, InGaAs, Si, SiN, Glass, Quartz, and SiON may be used as the device for the photonic IC 130, and various semiconductor materials such as Si, SiC, SiGe, and the like may be used as the device for the electronic IC 140. In order to mold the photonic IC 130 and the electronic IC 140, an encapsulation material such as an epoxy mold compound (EMC) and an epoxy resin may be used, and in a molding operation, several cells may be molded at a time at a wafer and panel level.

A redistribution layer 120 may be formed on the second surface (the upper surface) 114 of the mold body 110 formed by the encapsulation material, and the redistribution layer 120 may include terminal pads 150 for external connection of the package.

In order to form the insulating layer for the redistribution layer 120, various materials including polyimide (PI), poly (methylmethacrylate) (PMMA), benzocyclobutene (BCB), silicon oxide (SiO₂), acryl, and epoxy groups may be used, and a photo-lithography process may be used to form a wiring layer pattern.

In this case, the material of a wiring layer may serve as a photoresist (PR) capable of being developed, and the wiring layer may be etched after a PR coating is additionally performed. A process of depositing a metal is undergone after forming an insulating film, and the metal used for the redistribution layer 120 may include various metal materials such as Cu, Al, Au, and Ag, or a compound thereof.

The redistribution layer 120 shown in FIG. 1 is connected in two stages: a first interconnection between the photonic IC 130 and the electronic IC 140 from respective bonding pads 134a and 134b, and bonding pads 144a and 144b of the photonic IC 130 and the electronic IC 140, exposed to the second surface 114 of the mold body 110; and simultaneously a second interconnection of the bonding pads 134a and 134b, the bonding pads 144a and 144b, to terminal pads 150 on the upper part of the package by using first and second connection wires 126 and 128 made of metal formed on first and second insulating layers 122 and 124, respectively, to form a plurality of fan-out type terminal pads 150 for connection with the outside of the O-SIP 100.

The external connection terminal pads 150 formed on the redistribution layer 120 may be manufactured by directly exposing a metal surface of the redistribution layer 120 to the outside, such as a Land Grid Array (LGA) type, or mounting solder balls on an upper portion of the package, such as a Ball Grid Array (BGA) type, as shown in FIG. 1.

In this case, since the redistribution layer 120 includes a laser diode for generating an optical signal and/or a photodiode for receiving an optical signal, in the photonic IC 130, the first and second insulating layers 122 and 124 may be made of a transparent material as shown in FIG. 1 such that an optical signal is generated from the laser diode or an optical signal is received by the photodiode.

In addition, when the first and second insulating layers 122 and 124 are formed of an opaque material, the redistribution layer 120 may partially or entirely include an opening 136 through which an optical signal generated from the photonic IC 130 may pass, as shown in FIG. 2.

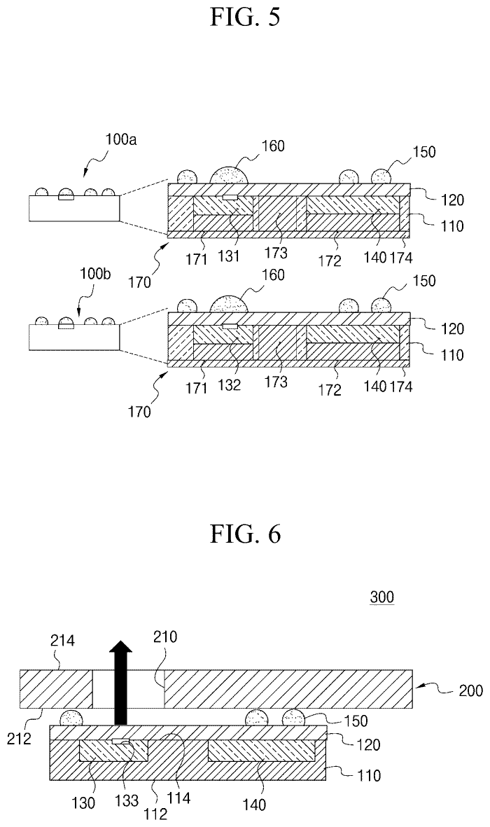

Furthermore, as illustrated in FIG. 5, the redistribution layer 120 may further include an optical lens 160 for changing (controlling) a path of light L generated from the photonic IC 130 even when the first and second insulating layers 122 and 124 include a transparent material.

For example, the optical lens 160 has a function of a collimating lens that creates a path close to parallel without dispersing the light L generated from the photonic IC 130 or a focusing lens that focuses the light L at one point.

As described above, the O-SIP 100 according to the first embodiment of the present invention may be implemented into an optical system-in-package (O-SIP) including the photonic IC 130 and the electronic IC 140 in the package to configure an optical engine module in a FOWLP method that does not use a via.

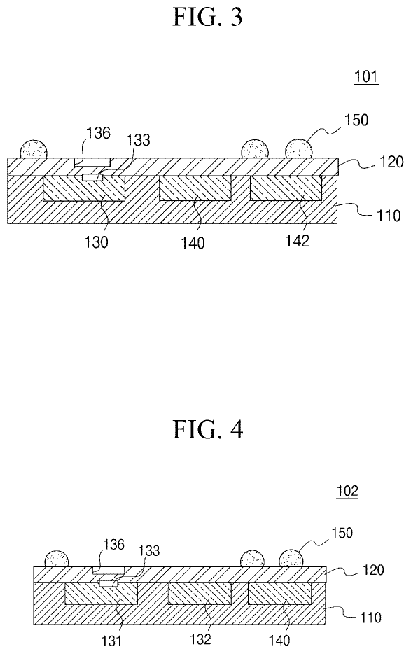

FIG. 3 is a cross-sectional view illustrating a package in which a photonic IC 130 and a plurality of electronic ICs 140 are embedded in an O-SIP 101 using semiconductor packaging according to a second embodiment of the present invention.

Although the O-SIP 100 using the semiconductor packaging according to the first embodiment includes a single photonic IC 130 and a single electronic IC 140, an O-SIP 101 using semiconductor packaging according to a second embodiment of the present invention may include a package in which a single photonic IC 130 and a plurality of electronic ICs 140 and 142 are embedded.

In addition, as shown in FIG. 4, an O-SIP 102 using semiconductor packaging according to a third embodiment of this invention may simultaneously use a light emitting device 131 such as a VCSEL and a light receiving device 132 such as a PD as photonic ICs.

As described above, in the O-SIP 102 according to the third embodiment of the present invention, since the light emitting device 131 and the light receiving device 132 as the photonic ICs are packaged inside the mold body 110 together with the electronic IC 140, optical signals may be transmitted and received using a SIP package in the form of one semiconductor chip.

The O-SIP 102 according to the third embodiment of the present invention may be used in a proximity sensor 302 shown in FIGS. 12A to 12C, as described later.

FIG. 5 is a cross-sectional view illustrating a package in which an transmitter optical sub-assembly (TOSA) and an receiver optical sub-assembly (ROSA) are separately formed and a heat dissipation metal structure is stacked on a first surface (lower surface) in an O-SIP using semiconductor packaging according to a fourth embodiment of the present invention.

Referring to FIG. 5, an O-SIP according to a fourth embodiment of the present invention may be separately configured into a TOSA 100a and a ROSA 100b.

In this case, the O-SIP according to the fourth embodiment of the present invention employs the light emitting device 131, such as a VCSEL, as the photonic IC in the case of the TOSA 100a, and employs the light receiving device 132 such as a PD as the photonic IC in the case of the ROSA 100b.

That is, the TOSA 100a may employ the light emitting device 131 such as a VCSEL as a photonic IC 130, and employ a driving circuit for driving the light emitting device 131 as an electronic IC 140. The redistribution layer 120 may be formed on the second surface 114 of the mold body 110, and a heat dissipation device 170 may be provided on the first surface 112 of the mold body 110.

The heat dissipation device 170 may include first and second metal structures 171 and 172 for heat dissipation under the photonic IC 130 and the electronic IC 140, respectively.

The sizes of the first and second metal structures 171 and 172 may be greater or less than those of the photonic IC 130 and the electronic IC 140, respectively.

As a method of forming the first and second metal structures 171 and 172, metal pieces may be attached to lower portions of the photonic IC 130 and the electronic IC 140, respectively, and then a FOWLP process may be performed in a state in which the metal pieces are attached to the photonic IC 130 and the electronic IC 140. In this case, a variety of adhesives may be used to attach the photonic IC 130 and the electronic IC 140 to the metal pieces, which may use silver epoxy or epoxy, EMC, or carbon nanotube (CNT) compound. For the best heat dissipation performance and electrical conductivity, a conductive material such as silver epoxy may be used. In the present invention, a conductive material may also be used to apply an electrical signal to the lower surfaces of the photonic IC 130 and the electronic IC 140.

In addition, when connecting the photonic IC 130 and the electronic IC 140 with the redistribution layer 120, a conductive structure in the form of a via should be formed in a FOWLP. In the present invention, a third metal structure 173 is molded together with other photonic IC 130 and electronic IC 140 during a FOWLP by using a PCB including via or a Cu piece. Subsequently, after grinding and flattening the third metal structure 173 so that the upper and lower metals of the third metal structure 173 for via are exposed, a metal connection layer 174 may be formed by depositing a metal under the photonic IC 130 and the electronic IC 140, and a redistribution layer 120 may be formed on the photonic IC 130 and the electronic IC 140.

As a result, the first and second metal structures 171 and 172 may be electrically connected to the redistribution layer 120 through the third metal structure 173 for via to be wired. In this case, a metal may be deposited on the bottom of the wafer at a wafer level to be connected without a pattern, or a wiring layer may be formed on the opposite surface of the redistribution layer 120 of the FOWLP wafer so as to be connected to each other as a double-sided wiring layer.

In the present invention, the redistribution layer 120 may be electrically connected to the metal connection layer 174 through the third metal structure 173 for via to use the metal connection layer 174 as a ground, and the heat of the redistribution layer 120 may be easily dissipated to the first surface (or the lower surface) 112 through the third metal structure 173 for via.

The ROSA 100b may also employ a light receiving device 130b, such as a photodiode PD, as the photonic IC 130, and employ an IC that performs functions of receiving and amplifying/converting the electrical signal obtained from the light receiving device 130b as the electronic IC 140.

In addition, the redistribution layer 120 may be formed on the second surface 114 of the mold body 110, and the first and second metal structures 171 and 172 for heat dissipation may be formed on the first surface 112 of the mold body 110 for additional heat dissipation under the photonic IC 130 and the electronic IC 140.

Furthermore, the first and second metal structures 171 and 172 for heat dissipation may be electrically connected to the redistribution layer 120 through the third metal structure 173 for via to be wired.

The O-SIP according to the fourth embodiment of the present invention may be electrically connected to the redistribution layer 120 through the third metal structure 173 for via of wide width, thereby minimizing inductance.

Meanwhile, the O-SIP 100 according to the present invention includes the photonic IC 130 and the electronic IC 140 in the mold body 110, and the redistribution layer (RDL) 120 including a plurality of terminal pads 150 is formed on the second surface (or the upper surface) 114 of the mold body 110.

In this case, instead of forming the first and second metal structures 171 and 172 for heat dissipation, the O-SIP 100 according to the present invention may be flattened so that the lower surfaces of the photonic IC 130 and the electronic IC 140 are exposed by grinding the first surface (or the lower surface) 112 of the mold body 110.

As described above, when the lower surfaces of the photonic IC 130 and the electronic IC 140 are exposed, heat dissipation may be directly performed.

In addition, the TOSA 100a may be used when implementing, for example, a TOF sensor.

FIG. 6 is a cross-sectional view illustrating an optical module in which an O-SIP according to the first embodiment is mounted in a main PCB according to a fifth embodiment of the present invention.

Referring to FIG. 6, an optical module 300 according to a fifth embodiment of the present invention may be obtained by mounting the O-SIP 100 according to the first embodiment on the main PCB 200.

For example, the O-SIP 100 according to the first embodiment may be formed by employing a light emitting device such as a VCSEL or a light receiving device such as a PD to the inside of the mold body 110, embedding the electronic IC 140, forming the redistribution layer 120 on the second surface 114 of the mold body 110, and forming the terminal pads 150 on the redistribution layer 120 using solder balls.

The O-SIP 100 having the structure described above may be mounted on the first surface (or the lower surface) 212 of the main PCB 200 by using solder balls of the terminal pads 150, and in this case, a surface mount technology (SMT) method may be used. In this case, various electronic components required to control transmission and reception of optical signals as optical modules 300 are mounted on the second surface (or the upper surface) 214 of the main PCB 200.

After the O-SIP 100 package device is mounted on the first surface (or the lower surface) 212 of the main PCB 200, an optical path entering and exiting the light entrance/exit part 133 of the photonic IC 130 of the O-SIP 100 package device may be formed inside the main PCB 200. In this case, an optical path passing through the main PCB 200 may be formed as shown in FIG. 6.

As shown in FIG. 6, a through hole 210 serving as a light passing window may be formed by processing a hole in the main PCB 200 to form an optical path, or a partial surface or an entire surface of the PCB may include a transparent material to form an optical path. The main PCB 200 may include a wiring pattern formed on Si or glass.

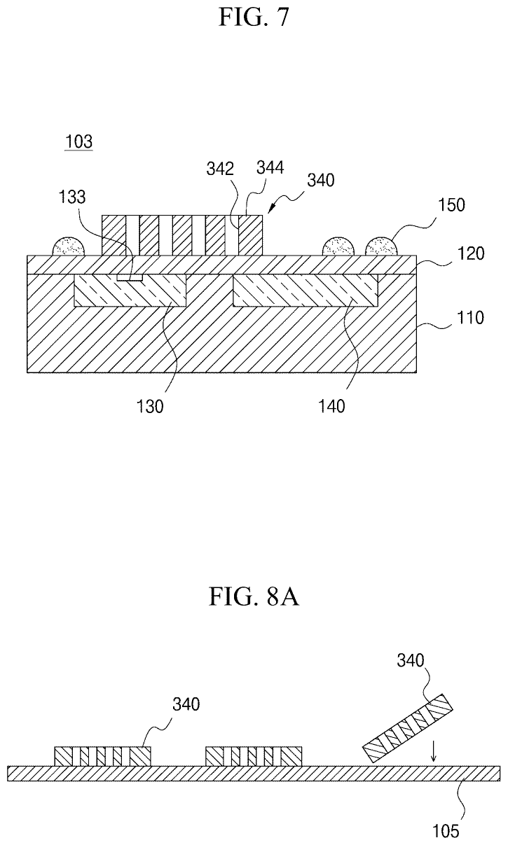

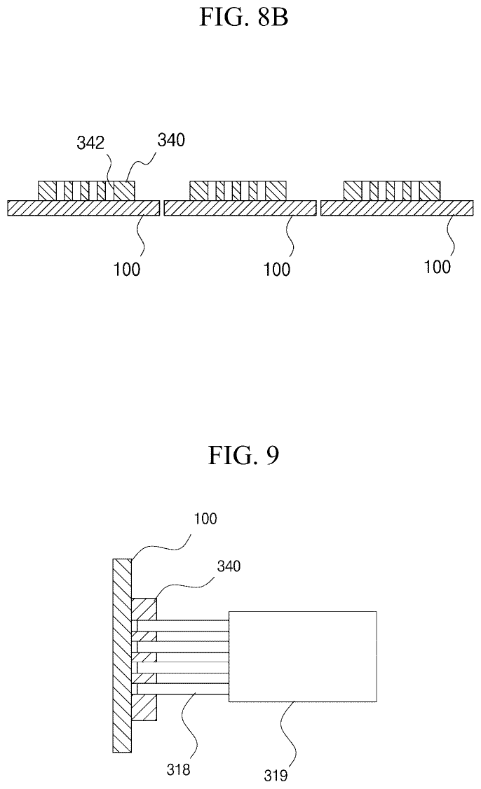

FIG. 7 is a cross-sectional view illustrating an optical module according to a sixth embodiment of the present invention in which a vertical coupler is coupled to the O-SIP according to the first embodiment, and FIGS. 8A and 8B are cross-sectional views illustrating a process of manufacturing an O-SIP to which a vertical coupler is coupled according to a sixth embodiment of the present invention.

Referring to FIGS. 7 to 8B, an optical module in which a vertical coupler 340 is coupled to an O-SIP 103 according to the sixth embodiment of the present invention is illustrated.

The O-SIP 103 is the same as the O-SIP 100 according to the first embodiment, and a detailed description thereof is omitted.

The vertical coupler 340 mounted on the upper surface of the O-SIP 103 has a structure in which a plurality of through holes 342 are formed in a body 344.

The photonic IC 130 embedded in the mold body 110 of the O-SIP 103 may be provided by forming four light emitting devices and/or four light receiving devices as one chip, for example, when being configured with four channels.

In this case, the vertical coupler 340 has four through holes 342, for example, formed in the body 344, and the four through holes 342 are formed at intervals facing the light entrance/exit parts 133 of the four light emitting devices and/or four light receiving devices, respectively.

In this invention, as shown in FIG. 8A, after manufacturing a wafer 105 by a FOWLP method to include a plurality of O-SIPs 100 according to the first embodiment, a plurality of pre-manufactured vertical couplers 340 are respectively aligned with light entrance/exit parts 133 of the light emitting devices and/or light receiving devices of the plurality of O-SIPs 100 using a Pick and Place (PnP) Machine and attached thereto in a bonding manner.

The vertical coupler 340 may be processed to have the through holes 342 through laser hole processing on a Si wafer. Alternatively, the vertical coupler 340 having the through holes 342 may be manufactured through plastic injection.

Alignment of the vertical coupler 340 may be performed at the wafer or panel level during the FOWLP process to increase assembly efficiency. Alternatively, after sawing/dicing the FOWLP wafer 105, the alignment of the vertical coupler 340 may be performed in the same way even after the O-SIP 100 is mounted to a control PCB 200 by using a surface mount technology (SMT) method.

Thereafter, as shown in FIG. 8B, the wafer 105 may be diced to obtain the O-SIP 103 according to the sixth embodiment in which the vertical coupler 340 is mounted on the O-SIP 100.

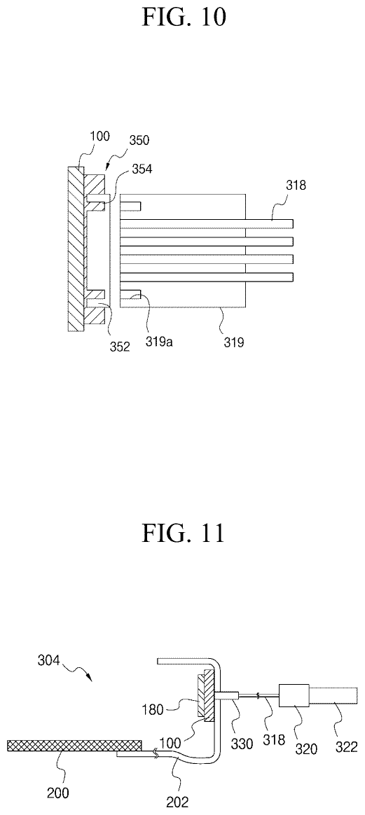

FIG. 9 is a cross-sectional view illustrating an optical module in which an optical fiber is directly coupled to an O-SIP to which a vertical coupler is coupled and obtained according to the sixth embodiment of the present invention, and FIG. 10 is a cross-sectional view illustrating an optical module in which a ribbon-shaped optical fiber holder is coupled to an O-SIP to which a vertical coupler is coupled according to a seventh embodiment of the present invention.

In the optical module of the present invention, it is possible to directly couple the optical fiber 318 without using an optical lens or the like by coupling the vertical coupler 340 to the O-SIP 100 employing a light emitting device that emits light in the vertical direction such as a VCSEL as the photonic IC 130 inside the mold body 110.

Referring to FIG. 9, in the O-SIP 103 according to the sixth embodiment, an optical module is shown in which a plurality of optical fibers 318 are directly coupled to a plurality of through holes 342 of the vertical coupler 340, respectively.

In this case, the plurality of optical fibers 318 may be accommodated in an optical fiber ribbon 319 to be integrated to facilitate handling.

The vertical couple 342 may include the plurality of through holes 342 accurately formed so that a plurality of optical fibers 318 may be accommodated. When the vertical coupler 340 is mounted on each of the plurality of O-SIPs 100 using a Pick and Place (PnP) Machine, both structures may be precisely aligned at predetermined positions through fiducial marks or holes precisely formed in the vertical coupler 340 or fiducial marks inside the O-SIP 100.

Referring to FIG. 10, in the optical module according to the seventh embodiment of the present invention, a modified vertical coupler 350 is mounted on the O-SIP 100 to increase a bonding force while accommodating a ribbon-shaped optical fiber holder 319 instead of the vertical coupler 340.

The modified vertical coupler 350 has an accommodation space formed therein to accommodate the ribbon-shaped optical fiber holder 319, and a pair of coupling protrusions 354 protrude from both sides of the accommodation space of the body.

The ribbon-shaped optical fiber holder 319 has a structure in which the front end portions of the plurality of optical fibers 318 are accommodated and integrated inside the body, and a pair of coupling recesses 319a coupled to the pair of coupling protrusions 354 are provided on both sides of the body.

Therefore, when the ribbon-shaped optical fiber holder 319 is assembled with the modified vertical coupler 350, the pair of coupling protrusions 354 may be combined with the pair of coupling recesses 319a to maintain the assembled state.

As described above, when the ribbon-shaped optical fiber holder 319 is assembled with the modified vertical coupler 350, the front end portions of the plurality of optical fibers 318 may be optically aligned with the light entrance/exit part 133 of the light emitting device and/or the light receiving device of the O-SIP 100, without using an optical lens or the like.

In the optical module according to the seventh embodiment of the present invention, the optical fibers 318 may be vertically aligned with the O-SIP 100. In this case, for alignment and bonding between the optical fibers 318 and the O-SIP 100, a ribbon-shaped optical fiber holder 319 surrounding the optical fibers 318 may be additionally used to supplement a fixed strength.

In order to perform optical alignment between the optical fibers 318 and the O-SIP 100, an active method may be used to measure and monitor light efficiency at the ends of the optical fibers, or a passive method described in FIG. 7 may be used.

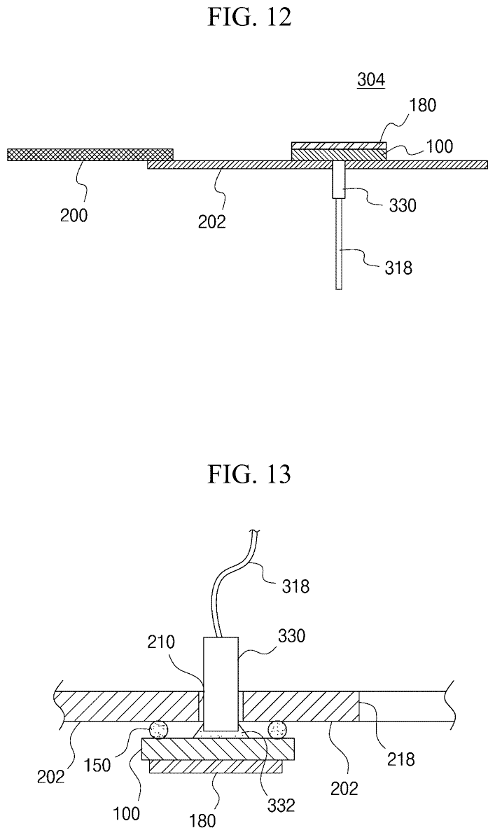

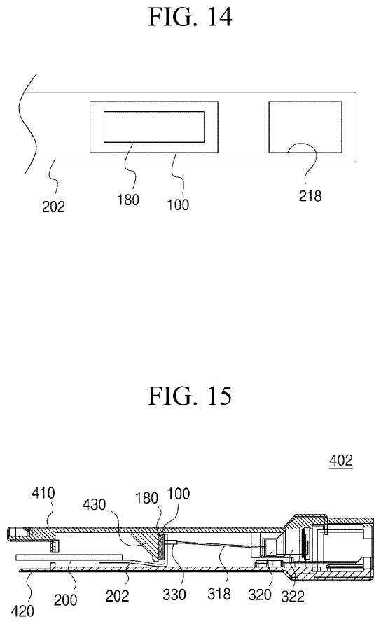

FIG. 11 is a cross-sectional view illustrating an optical module in which an O-SIP according to the first embodiment is mounted on a main PCB using a flexible printed circuit board (FPCB) according to an eighth embodiment of the present invention. FIG. 12 is a longitudinal cross-sectional view of an optical module according to the eighth embodiment of the present invention. FIG. 13 is an enlarged cross-sectional view illustrating a structure in which an optical fiber holder is directly coupled to an O-SIP in an optical module according to the eighth embodiment of the present invention. FIG. 14 is a partial enlarged view of an optical module according to the eighth embodiment of the present invention.

FIG. 15 is a cross-sectional view illustrating an optical transceiver implemented using an optical module according to the eighth embodiment of the present invention.

Referring to FIGS. 11 to 14, an optical module 304 according to an eighth embodiment of the present invention has a structure in which an O-SIP 100 according to the first embodiment is mounted on an FPCB 202 connected to the main PCB 200.

The O-SIP 100 according to the first embodiment is manufactured in advance with a TIM 180 attached to a rear surface for heat dissipation, and then mounted on the FPCB 202 in which a through hole 210 is formed.

The O-SIP 100 may be easily mounted on the FPCB 202 because, for example, solder balls are mounted on a terminal pad.

The O-SIP 100 is mounted on the FPCB 202 so that the through hole 210 of the FPCB 202 is aligned with the light entrance/exit part 133 of the light emitting device and/or the light receiving device.

The optical fiber 318 has a rear end portion to which an optical fiber holder 330 is coupled and a front end portion to which a LC receptacle 320 is connected.

In addition, a socket coupling part 322 to which a plug of an optical cable (not shown) is coupled protrudes from the front end portion of the LC receptacle 320.

Then, as shown in FIG. 13, after the optical fiber holder 330 may be fixed when the optical fiber holder 330 is inserted through the through hole 210 of the FPCB 202, when a sealing part 332 is formed by performing a sealing using epoxy while the front end portion is placed on the light entrance/exit part of the light emitting device and/or the light receiving device 133 of the O-SIP 100, the optical fiber holder 330 may be fixed.

Furthermore, the fixing of the optical fiber holder 330 by the epoxy sealing may be formed on the O-SIP 100 or the FPCB 202.

As described above, in the optical module 304 according to the eighth embodiment of the present invention, the optical fibers 318 may be easily coupled and fixed to the O-SIP 100 mounted on the FPCB 202 by inserting and fixing the optical fiber holder 330 through the through hole 210 of the FPCB 202.

As illustrated in FIG. 14, the FPCB 202 on which the O-SIP 100 is mounted may have a coupling hole 218 used to assemble to a housing of an optical transceiver 402 at the front end portion thereof.

As shown in FIG. 15, the optical module 304 according to the eighth embodiment of the present invention may be assembled inside an optical transceiver housing consisting of an upper housing 410 and a lower housing 420 to form the optical transceiver 402.

In this case, a coupling protrusion 430 that is coupled to the coupling hole 218 of the FPCB 202 protrudes inside the upper housing 410.

The front surface of the coupling protrusion 430 is formed at a right angle to tan inner peripheral surface of the upper housing 410, and a rear end portion thereof is inclined, so that the cross section of the coupling protrusion 430 is formed in a triangular shape.

Therefore, when the coupling hole 218 of the FPCB 202 is assembled to be caught by the coupling protrusion 430, the TIM 180 coupled to the O-SIP 100 is coupled so that a surface bonding is made on the front of the coupling protrusion 430. Furthermore, the optical module 304 in which the optical fiber holder 330 is assembled in the O-SIP 100 through the through hole 210 of the FPCB 202 includes a rear end portion connected to the main PCB 200 through the FPCB 202, and a front end portion connected to the LC receptacle 320 through the optical fibers 318.

As described above, the optical module 304 according to the eighth embodiment of the present invention is an embodiment in which the installation direction of the O-SIP 100 is given an angle rather than a horizontal direction when assembled inside the optical transceiver housing consisting of the upper housing 410 and the lower housing 420.

In this case, the optical fiber 318 may be directly optically coupled and assembled to the O-SIP 100 without using an additional structure such as an optical lens, thereby reducing components.

As described above, as shown in FIG. 15, the O-SIP 100 according to the present invention may be vertically erected with respect to the surface of the main PCB 200, or may be arranged with other angles (e.g., 30 degrees).

As a method of giving an angle to the arrangement of the O-SIP 100, the O-SIP 100 may be connected using the FPCB, and may be fixed by soldering after being vertically installed on the main PCB 200 in an embodiment not shown in the drawings. When using a FPCB, the O-SIP 100 may be installed on the FPCB 202, or may be arranged on a rigid PCB and then connected to the FPCB.

In both cases, light passes through the through hole 210 forming an optical path in the FPCB 202 below the light entrance/exit part 133 of the O-SIP 100 as shown in FIG. 12.

Accordingly, a body such as a terminal installed on one side is connected to at the rear end portion of the optical transceiver housing consisting of the upper housing 410 and the lower housing 420, and a plug of an optical cable (not shown) may be coupled to a socket coupling part 322 of the LC receptacle 320 at the front end portion to be connected to another terminal arranged on the other side.

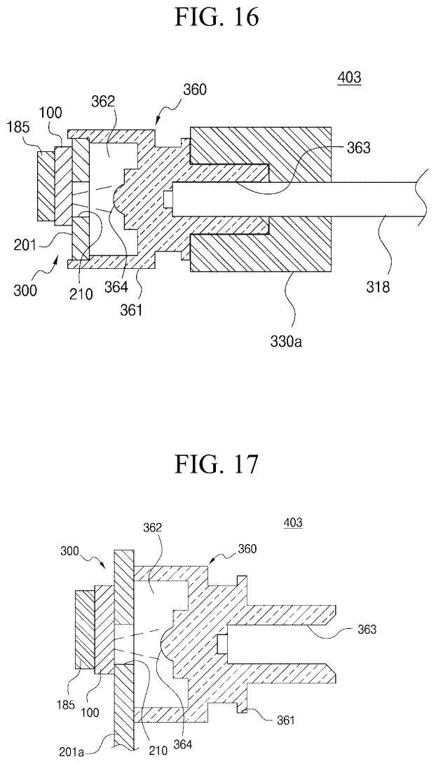

FIG. 16 is a cross-sectional view illustrating an optical transceiver in which an optical module using an O-SIP according to the first embodiment is connected to an optical fiber using a Lucent connection (LC) receptacle according to a ninth embodiment of the present invention, and FIG. 17 is a cross-sectional view illustrating an optical transceiver in which an optical module using an O-SIP according to the first embodiment is connected to the LC receptacle according to the ninth embodiment of the present invention.

The optical transceiver according to the ninth embodiment of the present invention has a structure in which an optical module to which the O-SIP 100 according to the first embodiment is applied is combined with the optical fibers 318 using the LC receptacle 360, and may be applied to a 5G network.

First, the O-SIP 100 according to the first embodiment is mounted on the main PCB 201 in which the through hole 210 is formed, and then assembled and fixed to the rear end portion of the LC receptacle 360.

A thermoelectric cooler (TEC) 185 for temperature control may be attached to the rear surface of the O-SIP 100. In this case, an operating temperature section of the O-SIP 100 may be extended. The TEC 185 is a cooler that uses the Peltier effect to generate a heat flux between two material junction points and cools by transferring heat from one side of a device to the other while consuming electrical energy according to a direction of a current.

For example, when a VCSEL is used as a light emitting device, the operating temperature is limited to 0° C. to 70° C., and if the TEC 185 is attached and used, the operating temperature may be widened from −40° C. to 85° C. The use of the TEC 185 may be equally applied to the structure of the O-SIP 100 described above. When the TEC 185 is used, a thermistor for temperature measurement may be embedded in the O-SIP 100.

A method of combining the optical module in which the O-SIP 100 is mounted on the main PCB 201 with the LC receptacle 360 may be performed in one of the following three methods.

First, the LC receptacle 360 has an accommodation space 362 on the rear end side of the body 361 to accommodate an optical module, an optical lens 364 is integrally formed in front of the accommodation space 362, and a cylindrical coupling protrusion having an optical fiber coupling groove 363 to which the optical fiber 318 is coupled is protruded on the center portion of the front end side of the body 361.

An optical fiber holder 330a is detachably coupled to the cylindrical coupling protrusion, and an optical fiber holder 330a has a coupling groove to which the cylindrical coupling protrusion is inserted and coupled at the rear end portion thereof, and the optical fiber 318 is supported at the center of the optical fiber holder 330a.

Accordingly, when the optical fiber holder 330a is assembled to the cylindrical coupling protrusion of the body 361, the front end portion of the optical fiber 318 is accommodated in the optical fiber coupling groove 363, and the optical axis alignment with the optical lens 364 may be achieved.

As illustrated in FIG. 16, the method of combining the optical module with the LC receptacle 360 may be performed by inserting and press-fitting the main PCB 201 of the optical module into the accommodation space 362 to be fixed at the rear end portion of the LC receptacle 360.

As shown in FIG. 17, according to the method of combining the optical module with the LC receptacle 360, the LC receptacle 360 may be attached to the main PCB 201a by manufacturing the main PCB 201a larger than the outer diameter of the LC receptacle 360.

In this case, the light passing through the through hole 210 of the main PCB 201a from the O-SIP 100 may be concentrated toward the optical fiber 318 through the optical lens 364 of the LC receptacle 360.

In this invention, for the alignment of the LC receptacle 360 and the optical fiber 318, an optical fiber holder 330a is combined with the front end portion of the LC receptacle 360 to insert the optical fiber 318 into the optical fiber coupling groove 363, and then an active method may be used in a manner in which the optical fiber holder 330a is fixed at a location where the optimal amount of light is obtained while measuring the amount of light of the optical fiber 318.

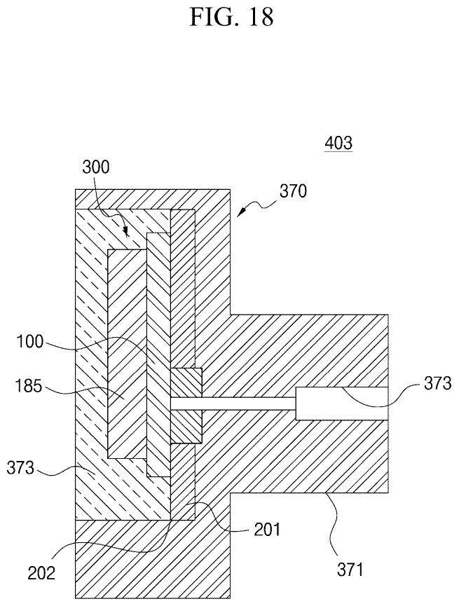

FIG. 18 is a cross-sectional view illustrating an optical transceiver in which an optical module in which an O-SIP according to the first embodiment is mounted on a main PCB according to a tenth embodiment of the present invention is combined with a LC receptacle and then sealed.

According to the method of combining the optical module with the LC receptacle 370 according to the tenth embodiment of the present invention, all the optical modules in which the O-SIP 100 is mounted on the main PCB 201 are inserted into the accommodation space at the rear end portion of the body 371 of the LC receptacle 370, and then the accommodation space 362 at the rear end portion of the LC receptacle 370 is filled with an epoxy sealing agent to form a sealing part 373.

The body 371 of the LC receptacle 370 has formed at a center portion thereof, an optical fiber coupling groove 373 to which the optical fiber 318 is inserted and coupled. Accordingly, when the optical fiber 318 is coupled to the optical fiber coupling groove 373, the front end portion of the optical fiber 318 may pass through the through hole 210 of the main PCB 201 and be aligned with the light entrance/exit part 133 of the O-SIP 100.

While the present invention has been particularly shown and described with reference to exemplary embodiments thereof, by way of illustration and example only, it is clearly understood that the present invention is not to be construed as limiting the present invention, and various changes and modifications may be made by those skilled in the art within the protective scope of the invention without departing off the spirit of the present invention.

### INDUSTRIAL APPLICABILITY

The present invention can be applied to an optical module including a photonic IC and an electronic IC in a package using an optical FOWLP that does not use a conductive via, and optical transceivers by using an optical system-in-package (O-SIP).

The present invention is directed to a method of implementing an O-SIP for integrating and packaging of systems using optical devices. Thus, the present invention may be used in various ways in the optical communication and optical sensor industries. For optical communication, communication between servers inside a data center, and optical transceivers for 5G and 6G communication networks may be used.

In addition, since miniaturization and integration are implemented in a package in the case of the present invention, the present invention may also be used for on-board optical communication and chip-to-chip optical communication. Moreover, the present invention may also be used for transmission of high-capacity audio and video data between TVs or electronic boards, and set-top boxes.

1. An optical module comprising:
an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body; and
a vertical coupler mounted on an upper portion of the O-SIP and having a through hole corresponding to a light entrance/exit part of the photonic IC inside the mold body, wherein
an optical fiber is coupled to the through hole.

2. The optical module of claim 1, wherein the O-SIP comprises a transmitter optical sub-assembly (TOSA) to which a light emitting device is applied as the photonic IC and a receiver optical sub-assembly (ROSA) to which a light receiving device is applied as the photonic IC.

3. The optical module of claim 1, wherein the photonic IC comprises a light emitting device and a light receiving device.

4. The optical module of claim 1, further comprising:
first and second metal structures for heat dissipation having respective upper surfaces bonded to lower portions of the photonic IC and the electronic IC and respective lower surfaces exposed;
a third metal structure for a via that is inserted through the mold body between the photonic IC and the electronic IC, and has an upper end connected to the RDL and a lower end exposed; and
a metal connection layer that connects the RDL to the lower portions of the photonic IC and the electronic IC and has a lower surface of the metal connection layer exposed by interconnecting the lower surfaces of the first to third metal structures.

5. The optical module of claim 1, wherein the O-SIP comprises:
the mold body having a first surface and a second surface which are flat on a lower portion and an upper portion of the mold body, respectively;
the photonic integrated circuit (IC) molded inside the mold body to expose a bonding pad on the first surface;
the electronic IC molded to be spaced apart from the photonic IC inside the mold body to expose the bonding pad on the first surface; and
a redistribution layer (RDL) formed on the second surface of the mold body and having a plurality of fan-out terminal pads electrically connected to the outside while interconnecting the photonic IC and the electronic IC.

6. The optical module of claim 5, wherein the RDL arranged on an upper portion of the light entrance/exit part of the photonic IC has an opening.

7. An optical module comprising:
an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body;
an optical fiber holder coupled to rear end portions of a plurality of optical fibers to support at least one optical fiber therein and having a pair of coupling recesses; and
a vertical coupler having a lower surface mounted on an upper portion of the O-SIP, having an accommodation space for accommodating the optical fiber holder at an upper end thereof, and having a pair of coupling protrusions protruding from both sides thereof to be coupled to the pair of coupling recesses.

8. The optical module of claim 7, wherein, when the optical fiber holder is coupled to the accommodation space of the vertical coupler, the at least one optical fiber is optically aligned with light entrance/exit part of a light emitting device or a light receiving device of the O-SIP.

9. An optical module comprising:
an optical system-in-package (O-SIP) for generating an optical signal or receiving an optical signal, in which a photonic integrated circuit (IC) and an electronic IC for driving or interfacing the photonic IC are molded inside a mold body having a first surface and a second surface which are flat on a lower portion and an upper portion of the mold body;
a first printed circuit board (PCB) having the O-SIP mounted on the lower surface thereof, and a through hole forming an optical path when an optical signal is generated in a vertical direction or an optical signal is received from the photonic IC at a portion corresponding to a light entrance/exit part of the photonic IC; and
an optical fiber holder coupled to rear end portions of a plurality of optical fibers so as to support the plurality of optical fibers therein, and having a front end portion on which the O-SIP is mounted through the through hole.

10. The optical module of claim 9, wherein the first PCB is a flexible PCB, and further comprising a second PCB on which a plurality of electronic components are mounted to perform transmission/reception control on the O-SIP, and to which one end of the first PCB is connected.

11.-15. (canceled)
